(19) United States
(12) Patent Application Publication
(10) Pub. No.: US 2026/0291383 A1
(43) Pub. Date: Sep. 24, 2026

(54) NOVEL INTEGRATED POWER MODULE

(71) Applicant: Flex Ltd., Singapore (SG)

(72) Inventors: Wei Xie, Shanghai (CN); Hongjie Li, Shanghai (CN); Xuefeng Yang, Shanghai (CN); Jing Gu, Shanghai (CN); Hongshan Tao, Shanghai (CN); Qiuhong Wang, Shanghai (CN)

(73) Assignee: Flex Ltd., Singapore (SG)

(21) Appl. No.: 19/181,914

(22) Filed: Apr. 17, 2025

(30) Foreign Application Priority Data
Mar. 20, 2025 (CN) 202510336080.6

(51) Int. Cl. H02M 3/00; H05K 1/14; H05K 1/181

(52) U.S. Cl. CPC H02M 3/003; H05K 1/14; H05K 1/181; H05K 2201/10015; H05K 2201/1003; H05K 2201/10166; H05K 2201/10522

(57) ABSTRACT

A power supply module includes an inductor, a first printed circuit board (PCB) provided orthogonal to the inductor at a first surface of the inductor and a second PCB provided orthogonal to the inductor at a second surface of the inductor via an inductor platform. The second PCB includes a plurality of output capacitors provided on a first surface of the second PCB and at least some of the plurality of output capacitors are provided underneath the inductor, between the second surface of the inductor and the first surface of the second PCB.

### CROSS-REFERENCE TO RELATED APPLICATIONS

The present application claims the benefit of and priority to Chinese Patent Application No. 202510336080.6 filed March 20, 2025, the entire disclosure of which is hereby incorporated by reference for all that it teaches and for all purposes.

### FIELD

The present disclosure is generally directed to power supplies, and more particularly, to multi-phase integrated power modules including a vertical printed circuit board (PCB) and output capacitors provided on a bottom PCB around and underneath an inductor secured to the bottom PCB.

### BACKGROUND

Power converters convert an input power to an output power for providing a load with a required voltage and current. Multi-phase power converters include a plurality of paralleled power stages operating out of phase having a lower output ripple voltage, a better transient performance and lower ripple-current-rating requirements for input capacitors.

One issue regarding multi-phase power converters is the footprint of the multi-phase power converters on a motherboard of an electronic component. Typically box pins or pin connectors are required to connect the multi-phase power converter with output capacitors provided on the motherboard. Adding more output capacitors can achieve a better dynamic performance for the converter (e.g., provide a quick transient load). The additional output capacitors, however, add to the footprint required by the multi-phase power converter on the motherboard.

A voltage regulator module (VRM) in a power supply is an electronic device that ensures the output voltage remains stable and within a specified range, despite variations in input voltage or fluctuations in the load current. The VRM can be a single phase VRM or a multi-phase VRM. The VRM’s primary function is to convert a fluctuating or higher input voltage to a steady, reliable output voltage suitable for powering sensitive electronics. The VRM is essential in providing the correct operating voltage for sensitive electronic devices like microprocessors, memory modules, and other components, preventing damage and ensuring optimal performance. In computer power supplies, VRMs are crucial for supplying power to the CPU and other high-performance components.

Accordingly, what is needed is a system and method for reducing the footprint of the multi-phase power converter on the motherboard of the electronic component by integrating output capacitors on the multi-phase power converter instead of on the motherboard.

### BRIEF SUMMARY

A power supply module including an inductor, a first printed circuit board (PCB) provided orthogonal to the inductor at a first surface of the inductor and a second PCB provided orthogonal to the inductor at a second surface of the inductor via an inductor platform. The second surface of the inductor is opposite to the first surface of the inductor and the second PCB includes a plurality of output capacitors provided on a first surface of the second PCB. Moreover at least some of the plurality of output capacitors are provided underneath the inductor, between the second surface of the inductor and the first surface of the second PCB.

Any of the aspects herein, wherein the inductor platform and the first surface of the inductor each includes at least one groove.

Any of the aspects herein, wherein the inductor platform and the first surface of the inductor each includes at least one pin extruded from the inductor platform and the first surface of the inductor.

Any of the aspects herein, wherein the at least one pin of the inductor platform is provided between the at least one groove.

Any of the aspects herein, wherein the at least one pin of the first side of the inductor is provided between the at least one groove.

Any of the aspects herein, wherein an adhesive is provided within the groove.

Any of the aspects herein, wherein the inductor has a square or circular shape.

Any of the aspects herein, wherein the first PCB includes at least one power device chip provided on a first surface of the first PCB.

Any of the aspects herein, wherein the first PCB further includes input capacitors provided on the first surface of the first PCB and provided around the at least power device chip.

Any of the aspects herein, further including a third PCB provided in parallel with the inductor at a third surface of the inductor.

Any of the aspects herein, wherein the third PCB transmits and receives signals from the first PCB and the second PCB.

Any of the aspects herein, wherein the third surface of the inductor is orthogonal to the first surface and the second surface of the inductor.

Any of the aspects herein, wherein the third PCB and the inductor are provided between the first PCB and the second PCB.

Any of the aspects herein, wherein more of the output capacitors are provided underneath the inductor, between the second surface of the inductor and the first surface of the second PCB than output capacitors that are not provided underneath the inductor.

A multi-phase power supply module includes a plurality of output voltage nodes, an inductor including a plurality of inductor packs, and a first printed circuit board (PCB) provided orthogonal to the inductor at a first surface of the inductor. The first PCB includes a first surface and a second surface. The multi-phase power supply module further includes a plurality of power chips provided on the first surface of the first PCB, a second PCB provided orthogonal to the inductor at a second surface of the inductor via an inductor platform and a plurality of output capacitors arranged on a first surface of the second PCB. The plurality of power chips are coupled to the plurality of inductors to provide a plurality of output voltages at the plurality of output voltage nodes and at least some of the plurality of output capacitors are provided underneath the inductor, between the second surface of the inductor and the first surface of the second PCB. Moreover, the plurality of output capacitors are coupled to the plurality of voltage nodes.

Any of the aspects herein, wherein the inductor platform and the first surface of the inductor each includes at least one groove.

Any of the aspects herein, wherein the inductor platform and the first surface of the inductor each includes at least one pin extruded from the inductor platform and the first surface of the inductor.

Any of the aspects herein, wherein the at least one pin of the inductor platform is provided between the at least one groove.

Any of the aspects herein, wherein the at least one pin of the first side of the inductor is provided between the at least one groove.

A method including providing an inductor, providing a first printed circuit board (PCB) orthogonal to the inductor at a first surface of the inductor and providing a second PCB orthogonal to the inductor at a second surface of the inductor via an inductor platform. The second surface of the inductor is opposite to the first surface of the inductor. The method further includes providing the second PCB with a plurality of output capacitors on a first surface of the second PCB and providing at least some of the plurality of output capacitors underneath the inductor, between the second surface of the inductor and the first surface of the second PCB.

### BRIEF DESCRIPTION OF THE DRAWINGS

FIG. 1 is a block diagram representing a schematic configuration of a multi-phase power module according to one embodiment of the present disclosure.

FIG. 2 is a perspective view of the multi-phase power module according to one embodiment of the present disclosure.

FIGS. 3A and 3B are exploded perspective views of the multi-phase power module according to one embodiment of the present disclosure.

FIG. 4 is a side view of the multi-phase power module according to one embodiment of the present disclosure.

FIGS. 5A and 5B are perspective views of an inductor of the multi-phase power module according to one embodiment of the present disclosure.

FIG. 6 is a block diagram of an electronic device that includes a power board including a plurality of multi-phase power modules according to one embodiment of the present disclosure.

FIG. 7 illustrates a flowchart of a method of manufacturing the multi-phase power module according to one embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

At least one example embodiment is directed to a power supply module. The power supply module includes an inductor, a first printed circuit board (PCB) and a second PCB. The first PCB is provided orthogonal to the inductor at a first surface of the inductor and the second PCB is provided orthogonal to the inductor at a second surface of the inductor via an inductor platform. The second surface of the inductor is opposite to the first surface of the inductor and the second PCB includes a plurality of output capacitors provided on a first surface of the second PCB. At least some of the plurality of output capacitors are provided underneath the inductor, between the second surface of the inductor and the first surface of the second PCB.

At least one example embodiment is directed to a multi-phase power supply module. The multi-phase power supply module includes a plurality of output voltage nodes, an inductor including a plurality of inductor packs, a first printed circuit board (PCB) provided orthogonal to the inductor at a first surface of the inductor, a second PCB provided orthogonal to the inductor at a second surface of the inductor via an inductor platform and a plurality of power chips provided on the first surface of the first PCB, wherein the plurality of power chips are coupled to the plurality of inductors to provide a plurality of output voltages at the plurality of output voltage nodes. The first PCB includes a first surface and a second surface. A plurality of output capacitors is arranged on a first surface of the second PCB. Moreover, at least some of the plurality of output capacitors are provided underneath the inductor, between the second surface of the inductor and the first surface of the second PCB, and the plurality of output capacitors are coupled to the plurality of voltage nodes.

At least one example embodiment is directed to a method. The method includes providing an inductor, providing a first printed circuit board (PCB) orthogonal to the inductor at a first surface of the inductor, providing a second PCB orthogonal to the inductor at a second surface of the inductor via an inductor platform, providing the second surface of the inductor opposite to the first surface of the inductor, providing the second PCB with a plurality of output capacitors on a first surface of the second PCB and providing at least some of the plurality of output capacitors underneath the inductor, between the second surface of the inductor and the first surface of the second PCB

The subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the subject matter may be practiced without these specific details. In other instances, well-known structures and devices are shown in block diagram form in order to facilitate describing the subject innovation.

Moreover, the word “exemplary” is used herein to mean serving as an example, instance, or illustration. Any aspect or design described herein as “exemplary” is not necessarily to be construed as preferred or advantageous over other aspects or designs. Rather, use of the word “exemplary” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. In addition, the word “coupled” is used herein to mean direct or indirect electrical or mechanical coupling.

The term “converter,” as used herein, encompasses but is not limited to any one of, or any combination of “regulator,” “DC regulator,” “voltage regulator,” “DC voltage regulator,” DC-to-DC converter,” “DC converter” and “converter,” and includes, but is not limited to, the plain meaning of any of these terms.

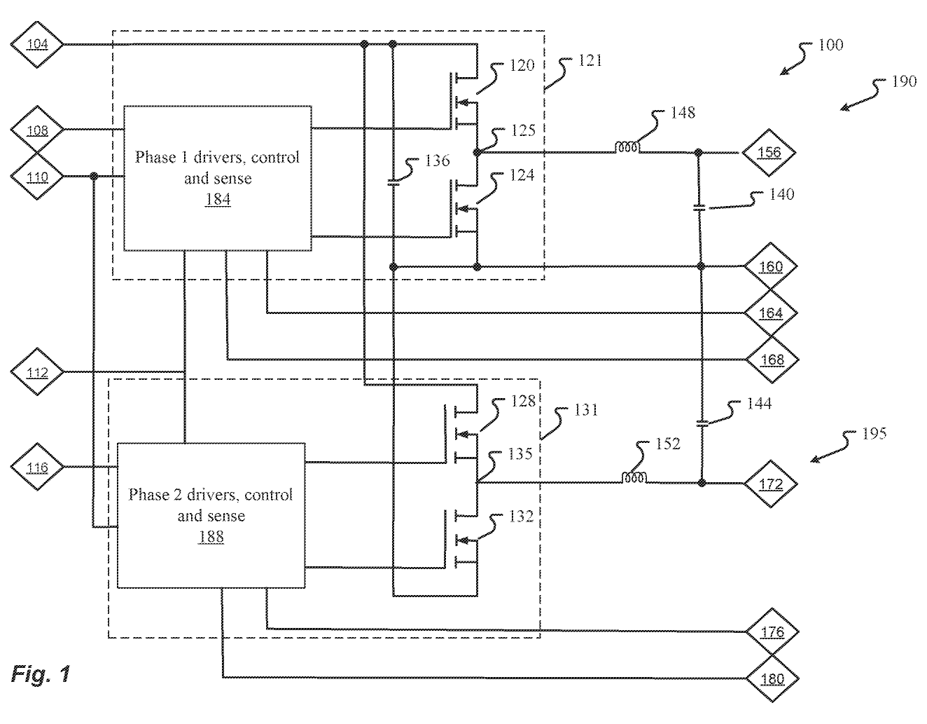

FIG. 1 shows a schematic diagram of a multi-phase power module 100 in accordance with an embodiment of the present disclosure. In the example of FIG. 1, the multi-phase power module 100 includes a pulse width modulated (PWM) controller (not shown), two power devices 121, 131, two inductors 148, 152 for supplying power to a load (not shown), two output capacitors 140, 144 and an input capacitor 136. Each power device 121, 131, inductor 148, 152, input capacitor 136 and output capacitor 140, 144 represents one power stage 190, 195 of the multi-phase power module 100. Each power device 121, 131 includes power switches 120, 124, 128, 132 and phase drivers, control and sense 184, 188 for driving the power switches 120, 124, 128, 132. The control and sense 184, 188 provide for sense: (power stage senses current/temperature signals where this information is sent to a controller) and control: (e.g., to implement the function (current share, over-current/temperature protection, etc.).

According to one embodiment of the present disclosure, the multi-phase power module 100 may be a buck converter. As can be appreciated, the multi-phase power module 100 may also be configured as a boost converter or other type of power converter depending on the application. Each phase of the multi-phase power module 100 may be connected to provide a multi-phase output voltage at the voltage output nodes 156, 172.

According to one embodiment of the present disclosure, each power device 121, 131 receives an input voltage VIN 104 and VCC 112, respectively, to generate an output voltage VOUT1 at voltage output node 156 and VOUT2 at voltage output node 172, respectively. The output voltages VOUT1, VOUT2 of the power devices 121, 131 may be connected together and interleaved to generate a multi-phase output voltage. For example, the output voltage node 156 and the output voltage node 172 may be connected together, with each power device 121, 131 providing a phase of a multi-phase output voltage.

The output capacitor 140 is connected to the output voltage node 156 and the output capacitor 144 is connected to the output voltage node 172. In the example of FIG. 1, the output capacitor 140 has a first end that is connected between the inductor 148 and the output voltage node 156 and a second end that is connected to ground 160. Similarly, the output capacitor 144 has a first end that is connected between the inductor 152 and the output voltage node 172 and a second end that is connected to ground 160. Other capacitors (e.g., input capacitor 136, supply capacitors, etc.) and other components not necessary to the understanding of the invention are not shown in FIG. 1 for clarity of illustration.

In one embodiment of the present disclosure, the power devices 121, 131 are implemented using an MP86976 Intelli-Phase™ Solution monolithic IC, which is commercially-available from Monolithic Power Systems, Inc. Other suitable monolithic IC’s may also be used without detracting from the merits of the present disclosure. The power devices 121, 131 have integrated therein, phase 1 drivers, control and sense 184, 188 and a pair of switches (e.g., Metal-Oxide-Semiconductor Field-Effect Transistor (MOSFET)). As shown in FIG. 1, the power device 121 has a first pin for receiving a PWM1 signal 108, a second pin for receiving an input voltage VIN 104, a third pin for connecting to ground 160, a fourth pin that is connected to a switch node 125 formed by the power switches 120, 124 and a fifth pin connected to an enable (EN) signal 110 (e.g., providing remote ON/OFF functions), a sixth pin connected to enable current sensor (ISEN1) signal 164 and a seventh pin connected to enable temperature sensor (TENS1) 168. The drain of the power switch 120 is connected to the input voltage VIN 104 and the source of the power switch 124 is connected to ground 160. The source of the power switch 120 is connected to the drain of the power switch 124 at the switch node 125.

Moreover, the power device 131 has a first pin for receiving a PWM2 signal 116, a second pin for receiving an input voltage VCC 112, a third pin for connecting to ground 160, a fourth pin that is connected to a switch node 135 formed by the power switches 128, 132, a fifth pin connected to enable EN signal 110, a sixth pin connected to enable current sensor (ISEN2) signal 176 and a seventh pin connected to enable temperature sensor (TENS2) 180. The drain of the power switch 128 is connected to the input voltage VCC 112 and the source of the power switch 132 is connected to ground 160. The source of the power switch 128 is connected to the drain of the power switch 132 at the switch node 135.

PWM control is well-known in the art. Briefly, the external PWM controller generates the PWM1 signal, which is received by the power device 121 at the first pin of the power device 121. The phase 1 drivers, control and sense 184 turns the power switches 120, 124 ON and OFF in accordance with the PWM1 signal 108. Turning the power switch 120 ON while turning the power switch 124 OFF connects the input voltage VIN 104 to the switch node 125 (by way of the power switch 120), whereas turning the power switch 120 OFF while turning the power switch 124 ON connects the switch node 125 to ground 160 (by way of the power switch 124). A first end of the inductor 148 is connected to the switch node 125 and a second end of the inductor 148 is connected between the output voltage node 156 and the output capacitor 140, where the output voltage VOUT1 is developed.

Moreover, the external PWM controller generates a PWM2 signal 116, which is received by the phase 2 drivers, control and sense 188 at the first pin of the power device 131. The phase 2 drivers, control and sense 188 turns the power switches 128, 132 ON and OFF in accordance with the PWM2 signal 116. Turning the power switch 128 ON while turning the power switch 132 OFF connects the input voltage VCC 112 to the switch node 135 (by way of the power switch 128), whereas turning the power switch 128 OFF while turning the power switch 132 ON connects the switch node 135 to ground 160 (by way of the power switch 132). A first end of the inductor 152 is connected to the switch node 135 and a second end of the inductor 1(52) is connected between the output voltage node 172 and the output capacitor 144, where the output voltage VOUT2 is developed.

In the example of FIG. 1, the external PWM controller generates the PWM signals PWM1 108 and PWM2 116 such that a corresponding output voltage VOUT1 156 and VOUT2 172 is maintained in regulation. Other circuits for implementing the PWM control, such as sense circuits (e.g., similar to the control and sense circuits discussed above) are not shown for clarity of illustration.

The input voltages VIN 104 and VCC 112, the output voltages VOUT1 156 and VOUT2 172 and the switching frequency of the power switches 120, 124, 128, 132 depend on the particulars of the monolithic IC switch block. In one embodiment of the present disclosure where the monolithic IC switch block is implemented using the aforementioned MP86976 Intelli-Phase™ Solution monolithic IC, the input voltages VIN 104 and VCC 112 are in the range of 3V to 7V, the output voltages VOUT1 156 and VOUT2 172 are in the range of 0.4V to 2V (e.g., 0.8V), and the switching frequency of the power switches 120, 124, 128, 132 are in the range of 1 MHz to 2 MHz (e.g., 1.5 MHz). The relatively low input voltages VIN 104 and VCC 112 and the relatively high switching frequency of the power switches 120, 124, 128, 132 allow for a relatively small physical size of the output inductors 148, 152 (e.g., 2.5 mm×5 mm×1.2 mm).

According to one embodiment of the present disclosure, input voltage VIN 104 may be in the range of 4.5V to 15V, input voltage VCC 112 may be 5V, output voltages VOUT1 156 and VOUT2 172 may be in the range of 0.75V to 1.3V and the switching frequency may be in the range of 500kHz to 1Mhz.

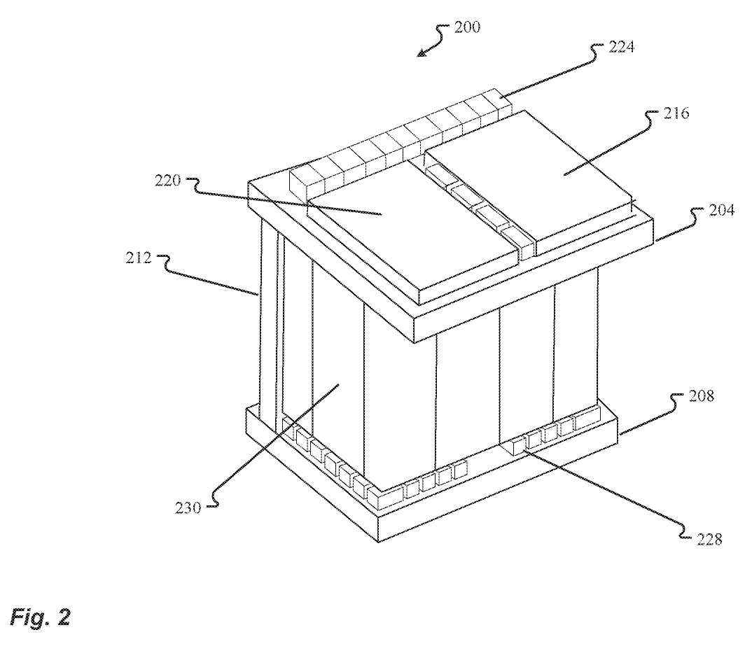

FIG. 2 is a perspective view of a multi-phase power module 200 according to one embodiment of the present disclosure. The multi-phase power module 200 generally includes a top printed circuit board (PCB) 204, a bottom PCB 208, a vertical PCB 212 provided between the top PCB 204 and the bottom PCB 208 and an inductor 230 provided in parallel with the vertical PCB 212 and between the top PCB 204 and the bottom PCB 208. The vertical PCB 212 is provided for transmitting and receiving signals from the top PCB 204 and the bottom PCB 208. Moreover, the vertical PCB 212 includes inner copper layers and is provided as an interface between the top PCB 204 and the bottom PCB 208. Incorporating the vertical PCB 212 improves the performance of the multi-phase power module 200 by decreasing alternating current (AC) losses and increasing immunity from interference in the two-phase power module.

According to an embodiment of the present disclosure, the vertical PCB 212 is provided as the connector for the top PCB 204 and the bottom PCB 208. The vertical PCB 212 is attached to the top PCB 204 and the bottom PCB 208 by soldering the boards for example. The vertical PCB 212 is a multi-layered board for example. The vertical PCB 212 multi-layered configuration is helpful for input power by the interleave design between the layers of the vertical PCB 212. Moreover, with the vertical PCB 212 being provided in close proximity to the inductor 230, the vertical PCB 212 acts as a shield to avoid signal disturbance regarding the inductor 230. According to a further embodiment of the present disclosure, the vertical PCB 212 further includes a half-hole design in the soldering edge to enhance solderability regarding the vertical PCB 212.

The inductor 230 may include an inductor pack including a plurality of inductors. The inductor 230 includes the inductor windings that are built into the core body of the inductor 230. The inductor windings are made of copper, for example and have a cylinder shape. The inductor core is made with metal powders, for example and the inductor core has a generally U-shaped configuration.

The top PCB 204 includes two power device chips 216 and 220 and discrete components 224 that may include resistors and capacitors of the multi-phase power module 200, like input capacitors at an input terminal to provide pulse current, filter capacitors and resistors for driver and internal logic circuits power supplies, etc. Each of the power device chips 216, 220 has one or more than one pins connected to one end of one of the inductor 230 of the inductor pack via the top PCB 204, wherein each inductor includes a winding.

The bottom PCB 208 includes output capacitors 228. As discussed in greater detail below, the output capacitors 228 are either provided around the inductor 230 or underneath the inductor 230 between the bottom surface of the inductor 230 and a top surface of the bottom PCB 208.

The two power device chips 216 and 220 represent the two power stages 190, 195 discussed above in FIG. 1. According to an embodiment of the present disclosure as illustrated in FIG. 2, the multi-phase power module 200 includes an integrated power stage with a continuous output current of 80 amperes (A), and a peak current of 140A. The multi-phase power module 200 has a compact footprint of just 0.9cm² (0.14 in²). According to a further embodiment of the present disclosure, the multi-phase power module 200 includes either land grid array (LGA) or solder bump termination for connecting the multi-phase power module 200 to a motherboard.

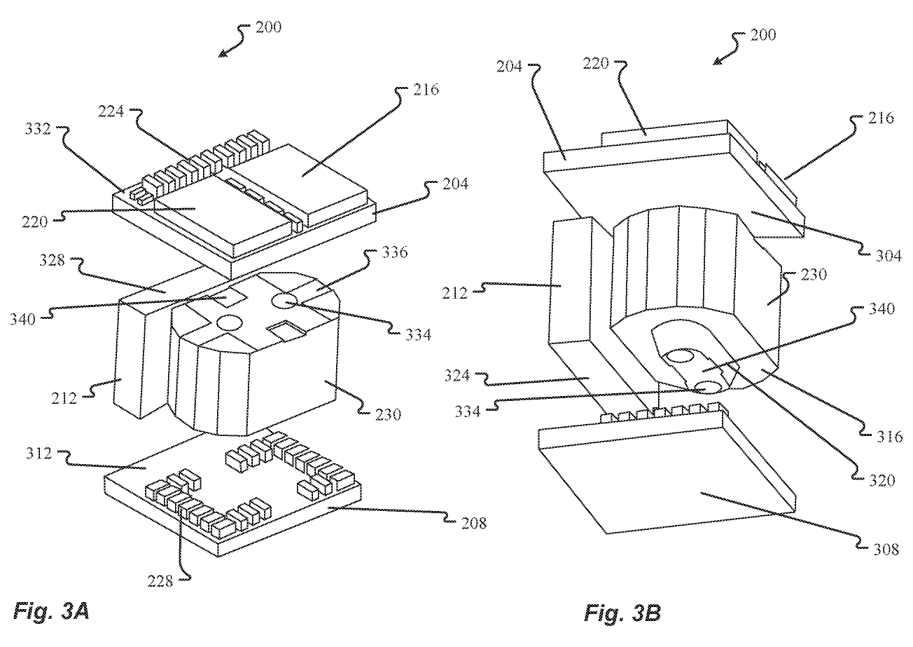

FIGS. 3A and 3B are exploded perspective views of a multi-phase power module 200 according to one embodiment of the present disclosure. As illustrated in FIGS. 3A and 3B, the inductor 230 includes a top side 336 and a bottom side 316. An inductor platform 320 is provided on the bottom side 316 of the inductor 230. According to an embodiment of the present disclosure, the inductor platform 320 includes at least one groove 340 and a plurality of pins 334. The at least one groove 340 includes an adhesive (e.g., glue) to secure the inductor platform 320 of the inductor 230 to a top surface 312 of the bottom PCB 208. Moreover, the plurality of pins 334 provide electrical conductivity between the inductor 230 and the bottom PCB 208. The inductor platform 320 is provided to raise the bottom surface 316 of the inductor 230 off from the top surface 312 of the bottom PCB 208. With the incorporation of the inductor platform 320, multiple output capacitors 228 can be provided directly on the top surface 312 of the bottom PCB 208.

The multiple output capacitors 228 can be provided either around the perimeter of the inductor 230 or underneath the inductor 230. According to an embodiment of the present disclosure, the inductor platform 320 raises the inductor 0.9 mm to 1.1 mm off from the top surface 312 of the bottom PCB 208 for example. According to a further embodiment of the present disclosure, at least 24 output capacitors 228 (e.g., 0402 output capacitors) are provided around and underneath the inductor 230 for example. The number of output capacitors 228 provided around and underneath the inductor 230 depends on the size of the output capacitors 228 for example. With this arrangement of the output capacitors 228 provided either around the perimeter of the inductor 230 or underneath the inductor 230, the overall footprint of the multi-phase power module 200 on a motherboard of an electronic device can be reduced. Moreover, the full space of the bottom PCB 208 may be utilized.

Also as illustrated in FIGS. 3A and 3B, a top side 336 of the inductor 230 includes at least one groove 340 and a plurality of pins 334. The at least one groove 340 includes an adhesive to secure the top side 336 to a bottom side 304 of the top PCB 204. Moreover, the plurality of pins 334 provide electrical conductivity between the top PCB 204 and the inductor 230.

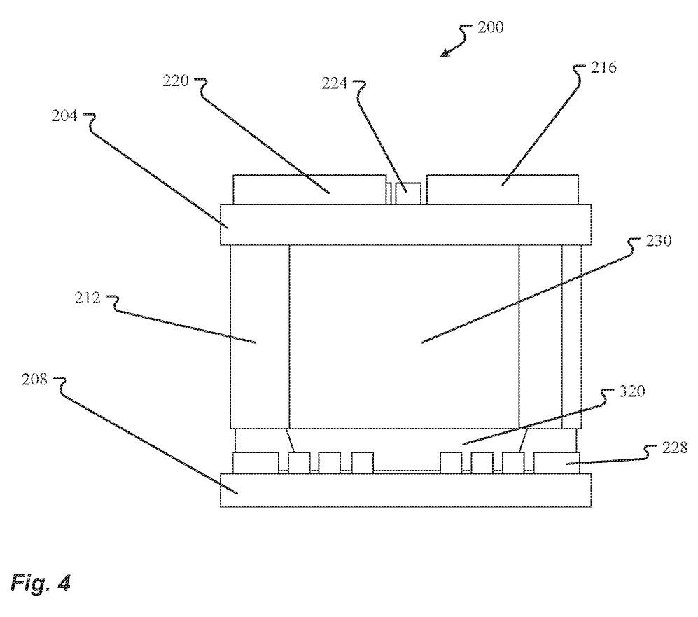

FIG. 4 is a side view of the multi-phase power module 200 according to one embodiment of the present disclosure. According to an embodiment of the present disclosure, the inductor 230 may have a square shape or a circular shape.

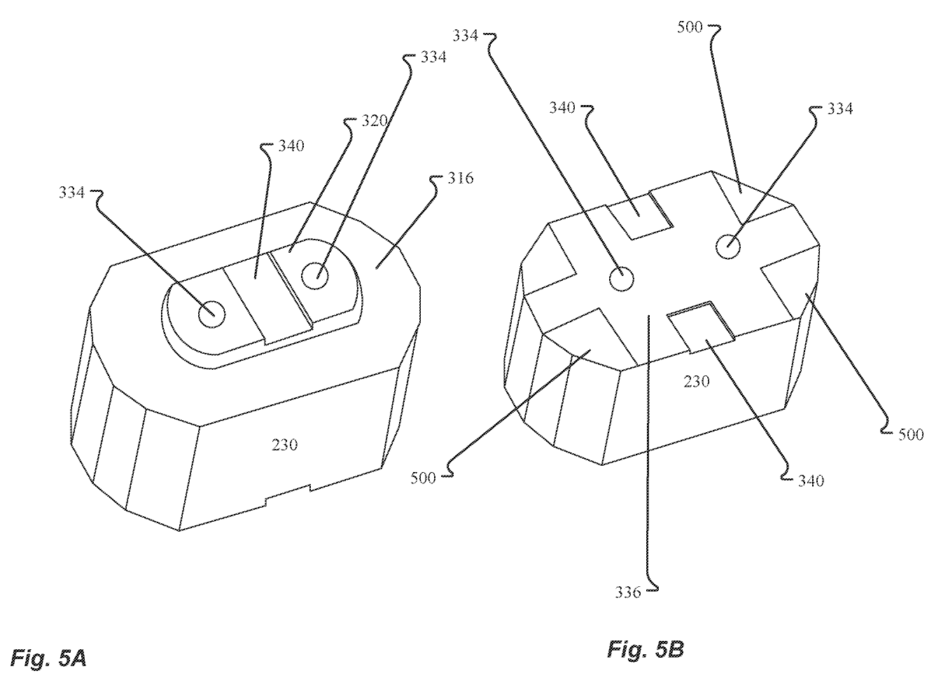

FIGS. 5A and 5B are perspective views of an inductor 230 of the multi-phase power module 200 according to one embodiment of the present disclosure. As illustrated in FIGS. 5A and 5B, the inductor 230 includes the top side 336 and the bottom side 316 with the inductor platform 320 provided on the bottom side 316 of the inductor 230. At least one groove 340 and a plurality of pins 344 are provided on the inductor platform 320 and the top side 336 of the inductor 230. The at least one groove 340 has a depth of approximately 0.2mm (implemented during a tooling process of the multi-phase power module 200). As stated above, the at least one groove 340 is provided to accommodate an adhesive (e.g., glue) to secure the inductor 230 to the corresponding top PCB 204 and bottom PCB 208 to meet the upside down reflow requirements during the manufacturing process of the multi-phase power module 200.

The plurality of pins 334 provide electrical conductivity between the inductor 230 and the top PCB 204 and the bottom PCB 208. As illustrated in FIG. 5B, the top surface 336 of the inductor 230 further includes a plurality of slots 500 provided around the plurality of pins 334. The plurality of slots 500 has a thickness of approximately 0.05mm and are provided to release gases which are generated during a soldering process in the manufacture of the multi-phase power module 200. By providing the plurality of slots 500 having a thickness of approximately 0.05mm, the risk of developing solder balls during the soldering process can be significantly reduced.

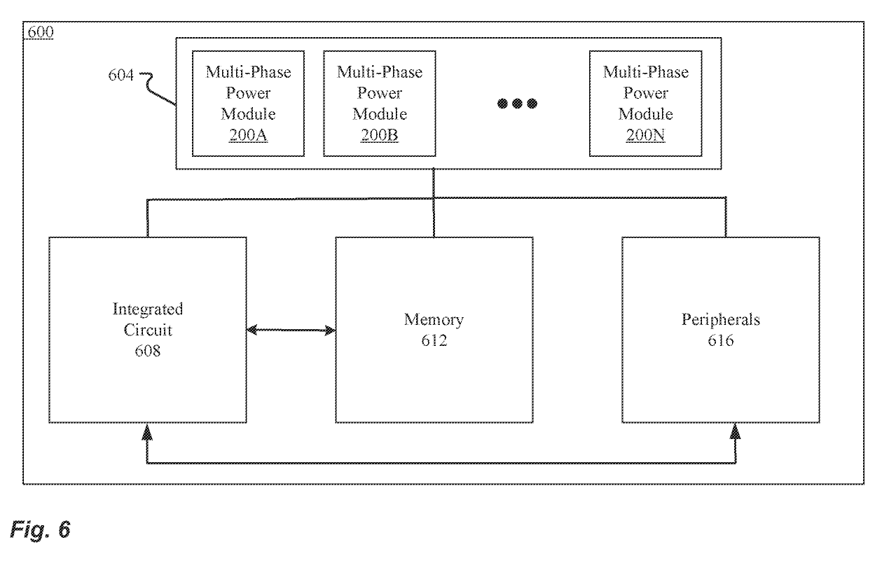

FIG. 6 is a block diagram of an electronic device 600 that includes a power board 604 including a plurality of multi-phase power modules 200 according to one embodiment of the present disclosure. The electronic device 600 includes at least one instance of an integrated circuit 608 coupled to external memory 612. The integrated circuit 608 may include a memory controller that is coupled to the external memory 612. The integrated circuit 608 is coupled to one or more peripherals 616 and the external memory 612. The power board 604 is also provided which supplies the supply voltages to the integrated circuit 608 as well as one or more supply voltages to the memory 612 and/or the peripherals 616. In some embodiments of the present disclosure, more than one instance of the integrated circuit 608 may be included (and more than one external memory 612 may be included as well).

The power board 604 includes a plurality of multi-phase power modules 200A-200N (as described above) that are arranged within the electronic device 600 to support the power demands of the electronic device 600, components, and/or peripherals 616. Based on the power requirements of the electronic device 600, a number of multi-phase power modules 200A-200N utilized by the electronic device 600 may be increased to satisfy the power requirements of the electronic device 600. Specifically, should the electronic device 600 require more than 600A peak current for a graphics processing unit (GPU) or a central processing unit (CPU), eight multi-phase power modules 200A-200N may be arranged within the electronic device 600 to provide 800A-880A. In some aspects of the present disclosure, integrating power converters onto an inductor core, as described above, the power board 604 is capable of providing high-current within a smaller footprint over conventional power supplies (which arrange components side-by-side), while reducing or eliminating electromagnetic noise and/or acoustic noise through cancellation (as described above). In another aspect of the present disclosure, each of the plurality of multi-phase power modules 200A-200N, during operation, provide current at a common target output voltage to a load.

The peripherals 616 may include any desired circuitry, depending on the type of electronic device 600. For example, in one embodiment of the present disclosure, the electronic device 600 may be a mobile device (e.g. personal digital assistant (PDA), tablet, laptop, smart phone, etc.) and the peripherals 616 may include devices for various types of wireless communication, such as WiFi, Bluetooth, cellular, global positioning system, etc. The peripherals 616 may also include additional storage, including RAM storage, solid-state storage, or disk storage. The peripherals 616 may include user interface devices such as a display screen, including touch display screens or multitouch display screens, keyboard or other input devices, microphones, speakers, etc. In other embodiments of the present disclosure, the electronic device 600 may be any type of computing system (e.g. desktop personal computer, workstation, watch, wearable device, and/or other type of computing system).

The external memory 612 may include any type of memory. For example, the external memory 612 may be SRAM, dynamic RAM (DRAM) such as synchronous DRAM (SDRAM), double data rate (DDR, DDR2, DDR3, LPDDR1, LPDDR2, etc.) SDRAM, RAMBUS DRAM, etc. The external memory 612 may include one or more memory modules to which the memory devices are mounted, such as single inline memory modules (SIMMs), dual inline memory modules (DIMMs), etc.

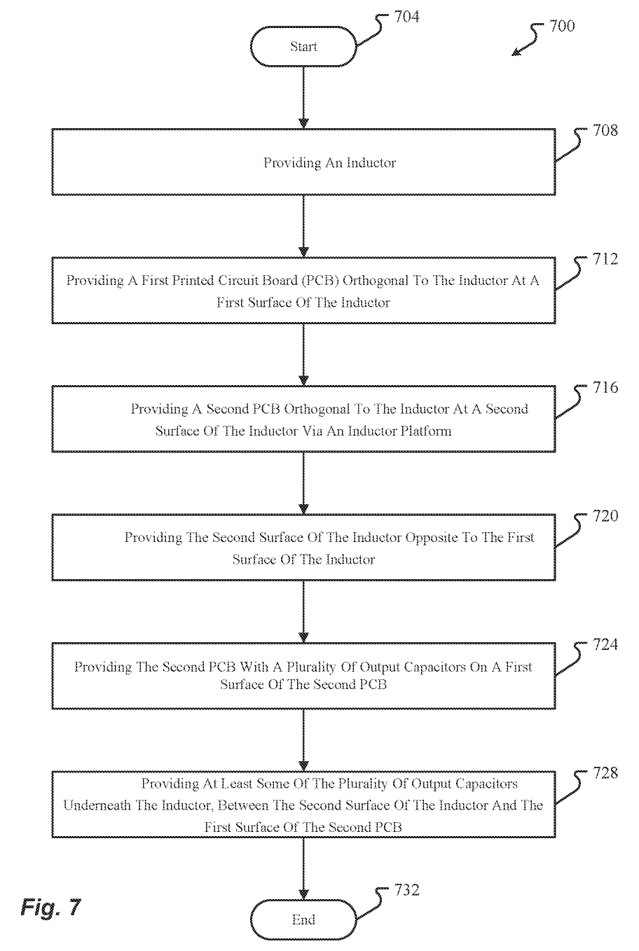

FIG. 7 illustrates a flowchart of a method 700 of manufacturing the multi-phase power module according to one embodiment of the present disclosure. While a general order for the steps of the method 700 of manufacturing the multi-phase power module according to one embodiment of the present disclosure is shown in FIG. 7, the method 700 can include more or fewer steps or can arrange the order of the steps differently than those shown in FIG. 7. Further, two or more steps may be combined into one step. Generally, the method 700 starts with a START operation 704 and ends with an END operation 732. Herein, method 700 shall be explained with reference to systems and components, modules, etc. described above.

Method 700 may start at START operation 704 and proceed to step 708 where an inductor is provided. After the inductor is provided at step 708, method 700 proceeds to step 712, where a first printed circuit board (PCB) is provided orthogonal to the inductor at a first surface of the inductor. After the first PCB is provided orthogonal to the inductor at the first surface of the inductor at step 712, method 700 proceeds to step 716 where a second PCB is provided orthogonal to the inductor at a second surface of the inductor via an inductor platform.

After the second PCB is provided orthogonal to the inductor at the second surface of the inductor via the inductor platform at step 716, method 700 proceeds to step 720 where the second surface of the inductor is provided opposite to the first surface of the inductor. After the second surface of the inductor is provided opposite to the first surface of the inductor at step 720, method 700 proceeds to step 724, where the second PCB is provided with a plurality of output capacitors on a first surface of the second PCB. After the second PCB is provided with the plurality of output capacitors on the first surface of the second PCB at step 724, method 700 proceeds to step 728, where at least some of the plurality of output capacitors are provided underneath the inductor, between the second surface of the inductor and the first surface of the second PCB. After at least some of the plurality of output capacitors are provided underneath the inductor, between the second surface of the inductor and the first surface of the second PCB at step 728, method 700 proceeds to the END operation 732 where method 700 may end.

Any of the steps, functions, and operations discussed herein can be performed continuously and automatically.

The exemplary devices, systems and methods of this disclosure have been described in relation to a power converter. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

Furthermore, while the exemplary embodiments illustrated herein show the various components of the system collocated, certain components of the system can be located remotely, at distant portions of a distributed network, such as a LAN and/or the Internet, or within a dedicated system. Thus, it should be appreciated, that the components of the system can be combined into one or more devices, such as a server, communication device, or collocated on a particular node of a distributed network, such as an analog and/or digital telecommunications network, a packet-switched network, or a circuit-switched network. It will be appreciated from the preceding description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

A number of variations and modifications of the disclosure can be used. It would be possible to provide for some features of the disclosure without providing others.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Exemplary hardware that can be used for the present disclosure includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably and include any type of methodology, process, mathematical operation or technique.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A power supply module, comprising:
an inductor;
a first printed circuit board (PCB) provided orthogonal to the inductor at a first surface of the inductor; and
a second PCB provided orthogonal to the inductor at a second surface of the inductor via an inductor platform,
wherein the second surface of the inductor is opposite to the first surface of the inductor,
wherein the second PCB includes a plurality of output capacitors provided on a first surface of the second PCB; and
wherein at least some of the plurality of output capacitors are provided underneath the inductor, between the second surface of the inductor and the first surface of the second PCB.

2. The power supply module of claim 1, wherein the inductor platform and the first surface of the inductor each includes at least one groove.

3. The power supply module of claim 2, wherein the inductor platform and the first surface of the inductor each includes at least one pin extruded from the inductor platform and the first surface of the inductor.

4. The power supply module of claim 3, wherein the at least one pin of the inductor platform is provided between the at least one groove.

5. The power supply module of claim 4, wherein the at least one pin of the first side of the inductor is provided between the at least one groove.

6. The power supply module of claim 5, wherein an adhesive is provided within the groove.

7. The power supply module of claim 1, wherein the inductor has a square or circular shape.

8. The power supply module of claim 1, wherein the first PCB includes at least one power device chip provided on a first surface of the first PCB.

9. The power supply module of claim 8, wherein the first PCB further includes input capacitors provided on the first surface of the first PCB and provided around the at least power device chip.

10. The power supply module of claim 1, further comprising a third PCB provided in parallel with the inductor at a third surface of the inductor.

11. The power supply module of claim 10, wherein the third PCB transmits and receives signals from the first PCB and the second PCB.

12. The power supply module of claim 10, wherein the third surface of the inductor is orthogonal to the first surface and the second surface of the inductor.

13. The power supply module of claim 10, wherein the third PCB and the inductor are provided between the first PCB and the second PCB.

14. The power supply module of claim 1, wherein more of the output capacitors are provided underneath the inductor, between the second surface of the inductor and the first surface of the second PCB than output capacitors that are not provided underneath the inductor.

15. A multi-phase power supply module, comprising:
a plurality of output voltage nodes;
an inductor including a plurality of inductor packs;
a first printed circuit board (PCB) provided orthogonal to the inductor at a first surface of the inductor,
wherein the first PCB includes a first surface and a second surface;
a plurality of power chips provided on the first surface of the first PCB, wherein the plurality of power chips are coupled to the plurality of inductors to provide a plurality of output voltages at the plurality of output voltage nodes;
a second PCB provided orthogonal to the inductor at a second surface of the inductor via an inductor platform,
a plurality of output capacitors arranged on a first surface of the second PCB,
wherein at least some of the plurality of output capacitors are provided underneath the inductor, between the second surface of the inductor and the first surface of the second PCB, and
wherein the plurality of output capacitors are coupled to the plurality of voltage nodes.

16. The multi-phase power supply module of claim 15, wherein the inductor platform and the first surface of the inductor each includes at least one groove.

17. The multi-phase power supply module of claim 16, wherein the inductor platform and the first surface of the inductor each includes at least one pin extruded from the inductor platform and the first surface of the inductor.

18. The multi-phase power supply module of claim 17, wherein the at least one pin of the inductor platform is provided between the at least one groove.

19. The multi-phase power supply module of claim 18, wherein the at least one pin of the first side of the inductor is provided between the at least one groove.

20. A method, comprising:
providing an inductor;
providing a first printed circuit board (PCB) orthogonal to the inductor at a first surface of the inductor;
providing a second PCB orthogonal to the inductor at a second surface of the inductor via an inductor platform,
wherein the second surface of the inductor is opposite to the first surface of the inductor;
providing the second PCB with a plurality of output capacitors on a first surface of the second PCB; and
providing at least some of the plurality of output capacitors underneath the inductor, between the second surface of the inductor and the first surface of the second PCB.
